(19) United States
(12) Patent Application Publication
(10) Pub. No.: US 2021/0013866 A1
(43) Pub. Date: Jan. 14, 2021

(54) SYSTEMS AND METHODS FOR SAW WAFER LEVEL ASSEMBLY WITH TOP SIDE CONTACTS

(71) Applicant: General Electric Company, Schenectady, NY (US)

(72) Inventors: Joseph Alfred Iannotti, Glenville, NY (US); Christopher James Kapusta, Delanson, NY (US)

(21) Appl. No.: 16/509,554

(22) Filed: Jul. 12, 2019

(51) Int. Cl. H03H 9/10; H03H 9/05; H03H 3/08

(52) U.S. Cl. CPC H03H 9/1092; H03H 3/08; H03H 9/058

(57) ABSTRACT

A wafer level assembly is disclosed. The wafer level assembly includes a device wafer, and a plurality of electrodes disposed on the device wafer, wherein the device wafer the plurality of electrodes form a surface acoustic wave (SAW) device, a plurality of device pads disposed on the device wafer, wherein each of the plurality of electrodes are coupled to one of the device pads, a cap wafer coupled to the device wafer through a seal layer, the cap wafer having a plurality of contact pads and a plurality of interconnect pads integral with a surface of the cap wafer, wherein each of the plurality of contact pads is coupled to one of the plurality of interconnect pads, and a plurality of conductive interconnects, wherein each of the plurality of conductive interconnects is coupled between one of the plurality of device pads and one of the plurality of interconnect pads.

### BACKGROUND

The field of the invention relates generally to surface acoustic wave (SAW) devices, and more particularly, to a SAW wafer level assembly having integral top side contacts.

SAW devices rely on surface acoustic waves on a piezoelectric substrate between interdigitated transducers to provide a number of different functions. For example, SAW devices may serve as filters, oscillators, or sensors that detect, for example, pressure, torque, or temperature.

Challenges exist in installation of the SAW device within an application circuit. For example, the surface where waves propagate must be kept clean. Further, depending on the particular application, SAW sensors may be subjected to harsh environments that may damage or otherwise limit the useful life of the SAW sensor. In addition, SAW devices require a suitable interconnect in order to couple to an external device, such as an antenna or a transmission line. For example, at least some known SAW devices utilize thin 2000 angstrom aluminum metallization, which is generally not suitable for a robust interconnect for harsh environments.

At least some known SAW devices utilize a printed circuit board (PCB) attached to the SAW device to provide such bond pads. However, attaching a PCB to the SAW device complicates manufacture and reduces reliability of the SAW device. A more reliable SAW device assembly is therefore desirable.

### BRIEF DESCRIPTION

In one aspect, a device assembly is disclosed. The device assembly includes a device wafer, and a plurality of electrodes disposed on the device wafer, wherein the device wafer the plurality of electrodes form a surface acoustic wave (SAW) device. The device assembly further includes a plurality of device pads disposed on the device wafer, wherein each of the plurality of electrodes are electrically coupled to at least one of the device pads. The device assembly further includes a cap wafer coupled to the device wafer through a seal layer. The cap wafer has a plurality of contact pads and a plurality of interconnect pads integral with a surface of the cap wafer, wherein each of the plurality of contact pads is electrically coupled to one of the plurality of interconnect pads. The device assembly further includes a plurality of conductive interconnects, wherein each of the plurality of conductive interconnects is electrically coupled between one of the plurality of device pads and one of the plurality of interconnect pads.

In another aspect, a cap wafer assembly is disclosed. The cap wafer assembly includes a cap wafer including a plurality of contact pads and a plurality of interconnect pads integral with a surface of the cap wafer, wherein each of the plurality of contact pads is electrically coupled to one of the plurality of interconnect pads, and wherein the cap wafer is coupled to a SAW device including a device wafer, a plurality of electrodes disposed on the device wafer, and a plurality of device pads disposed on the device wafer and electrically coupled to at least one of the electrodes. The cap wafer assembly further includes a plurality of conductive interconnects, wherein each of the plurality of conductive interconnects is electrically coupled between one of the plurality of device pads and one of the plurality of interconnect pads.

### DRAWINGS

These and other features, aspects, and advantages of the present disclosure will become better understood when the following detailed description is read with reference to the accompanying drawings in which like characters represent like parts throughout the drawings, wherein:

FIG. 1 is depicts a side cross-sectional view of an exemplary SAW device assembly.

FIG. 2 depicts a top view of the exemplary SAW device assembly shown in FIG. 1.

FIG. 3 depicts a side cross-sectional view of another exemplary SAW device assembly.

FIG. 4 depicts a top view of the exemplary SAW device shown in FIG. 3.

FIG. 5 depicts a side cross-sectional view of another exemplary SAW device assembly.

FIG. 6 depicts a top view of the exemplary SAW device assembly shown in FIG. 5.

FIG. 7 depicts a side cross-sectional view of another exemplary SAW device assembly.

FIG. 8 depicts a top view of the exemplary SAW device assembly shown in FIG. 7

FIG. 9 depicts an exemplary method for manufacturing a SAW device assembly.

FIG. 10 depicts a top view of a SAW wafer level assembly.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

The systems and methods described herein provide a SAW wafer level assembly having a cap wafer with integral contact pads.

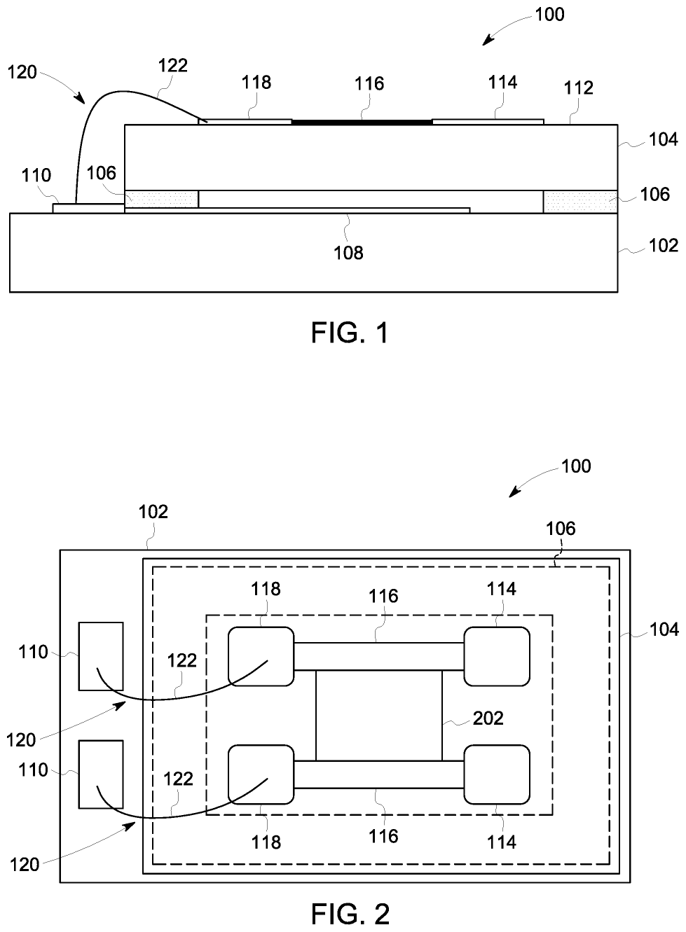

FIG. 1 depicts a side cross-sectional view of a SAW device assembly 100 according to an exemplary embodiment of the present disclosure. FIG. 2 depicts a top view of SAW device assembly 100. SAW device assembly 100 includes a device wafer 102 and a cap wafer 104. Device wafer 102 is attached to cap wafer 104 by a seal layer 106. In some embodiments, seal layer 106 may be, for example, a liquid crystal polymer (LCP) or glass frit bonding layer forming a hermetic seal between device wafer 102 and cap wafer 104.

Device wafer 102 includes a piezoelectric substrate such as quartz. Electrodes 108 are disposed on device wafer 102 and electrically coupled to device pads 110. In some embodiments, electrodes 108 may be hermetically sealed within a cavity formed by device wafer 102, cap wafer 104, and seal layer 106. Electrodes 108 are configured to convert surface acoustic waves in the piezoelectric substrate of device wafer 102 into an electric signal at device pads 110. In some embodiments, electrodes 108 may include an interdigitating structure such as an interdigitated transducer (IDT).

Cap wafer 104 includes a surface 112 on which contact pads 114 are formed. Contact pads 114 enable SAW device assembly 100 to be coupled to external devices. For example, contact pads 114 may be configured to couple to a radio frequency (RF) transmission line or antenna. Contact pads 114 may be formed with a wide range of metallurgies to accommodate various interconnect requirements. For example, in some embodiments, contact pads 114 may be configured for solder, ball grid array (BGA), surface mount technology (SMT), or wirebond coupling. Contact pads 114 are electrically coupled to device pads 110 through pad to pad interconnects 116, interconnect pads 118, and conductive interconnects 120. In some embodiments, cap wafer 104 includes a quartz substrate on which contact pads 114, pad to pad interconnects 116, and interconnect pads 118 are formed.

Contact pads 114, pad to pad interconnects 116, and interconnect pads 118 are integral to surface 112 of cap wafer 104 and can be made of, for example, titanium, copper, nickel, gold, or other combinations of such. In some embodiments, contact pads 114 and interconnect pads 118 are formed by depositing a conductive material directly onto surface 112 of cap wafer 104, for example, through a direct metallization or sputtering process. In some embodiments, pad to pad interconnects 116 may be a conductive trace formed through a printing process using conductive inks such as gold or copper. Contact pads 114, pad to pad interconnects 116, and interconnect pads 118 can be formed on cap wafer 104 prior to assembly of SAW device assembly 100, simplifying the assembly process. For example, contact pads 114, pad to pad interconnects 116, and interconnect pads 118 may be printed or sputtered during the wafer-level manufacture of cap wafer 104 and prior to bonding cap wafer 104 to device wafer 102. Further, because contact pads 114, pad to pad interconnects 116, and interconnect pads 118 are integral to surface 112 of cap wafer 104, contact pads 114, pad to pad interconnects 116, and interconnect pads 118 cannot readily become dislodged from cap wafer 104, providing enhanced reliability under harsh conditions. Further, contact pads 114, pad to pad interconnects 116, and interconnect pads 118 enable second level interconnect techniques that are not suitable for direct connection to device pads 110, such as solder or gold wirebonding.

Conductive interconnects 120 are electrically coupled to respective device pads 110 and interconnect pads 118 and provide a conductive path between components positioned on device wafer 102 and components positioned on cap wafer 104. In the exemplary embodiment, conductive interconnects 120 include wirebonds 122, where each wirebond 122 is bonded to one device pad 110 and one interconnect pad 118. In some embodiments, multiple wirebonds 122 may be coupled between a device pad 110 and an interconnect pad 118 for redundancy. While one wirebond 122 is shown for each device pad 110 and respective interconnect pad 118, in other embodiments, a plurality of wirebonds 122 may be bonded to each device pad 110 and interconnect pad 118. In some embodiments, wirebonds 122 may be covered by a coating such as an epoxy resin (i.e., “glob top”) or pyralene for protection.

In some embodiments, SAW device assembly 100 may include passive electronic components 202 (shown in FIG. 2). Passive electronic components 202 may include, for example, inductors, capacitors, and/or resistors. Passive electronic components 202 may form, for example, an impedance matching device. In some embodiments, passive electronic components 202 may include an antenna configured to facilitate wireless communication for SAW device assembly 100. In some embodiments, at least some of passive electronic components 202 may be surface mount components mounted on surface 112 of cap wafer 104. Additionally or alternatively, at least some of passive electronic components 202 may be printed components that are printed directly onto surface 112 of cap wafer 104, for example, as distributed microstrip elements. In such embodiments, passive electronic components 202 may be printed onto cap wafer 104 prior to or during assembly of SAW device assembly 100, simplifying the assembly process. For example, passive electronic components 202 may be printed, sputtered, or attached to cap wafer 104 during the wafer-level manufacture of cap wafer 104 and prior to bonding cap wafer 104 to device wafer 102.

In some embodiments, SAW device assembly 100 may be encased in an overmold material. For example, a high temperature resistant material having a low elastic modulus, such as silicone or pyralene coating, may be used as an overmold material. The overmold material may provide additional protection for SAW device assembly 100.

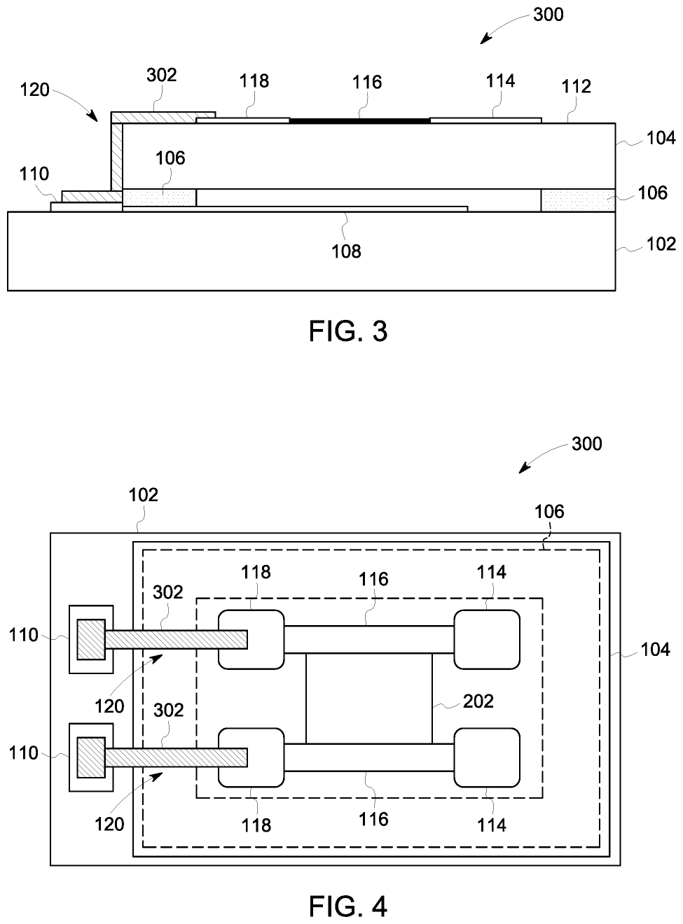

FIG. 3 depicts a side cross-sectional view of another SAW device assembly 300 according to an exemplary embodiment of the present disclosure. FIG. 4 depicts a top view of SAW device assembly 300. SAW device assembly 300 includes device wafer 102, cap wafer 104, seal layer 106, electrodes 108, device pads 110, contact pads 114, pad to pad interconnects 116, interconnect pads 118, conductive interconnects 120 (all shown in FIG. 1), and passive electronic components 202 (shown in FIG. 2), which operate generally as described with respect to FIGS. 1 and 2.

In the embodiment shown in FIG. 3, conductive interconnects 120 include respective printed conductive traces 302. Printed conductive traces 302 may be formed through a printing process, for example, using conductive ink or conductive paste. Printed conductive traces 302 are electrically coupled to associated device pads 110 and interconnect pads 118 and provide a conductive path between components positioned on device wafer 102 and components positioned on cap wafer 104. Because printed conductive traces 302 have a low physical profile and are firmly integrated with cap wafer 104, printed conductive traces 302 provide enhanced durability and reliability, for example, in high G-force applications.

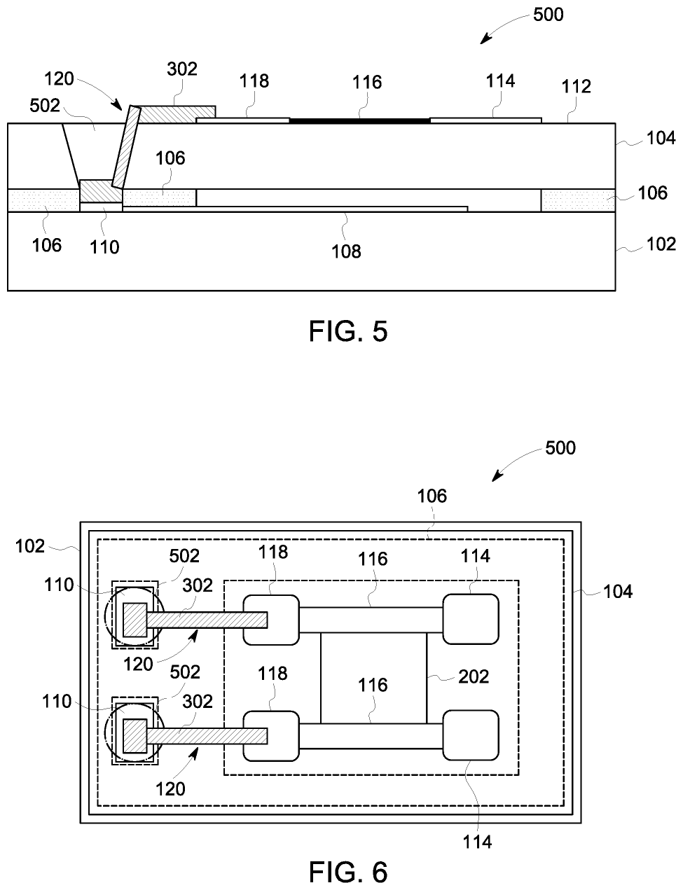

FIG. 5 depicts a side cross-sectional view of another SAW device assembly 500 according to an exemplary embodiment of the present disclosure. FIG. 6 is a top view of SAW device assembly 500. SAW device assembly 500 includes device wafer 102, cap wafer 104, seal layer 106, electrodes 108, device pads 110, contact pads 114, pad to pad interconnects 116, interconnect pads 118, conductive interconnects 120 (all shown in FIG. 1), passive electronic components 202 (shown in FIG. 2), and printed conductive traces 302 (shown in FIG. 3), which operate generally as described with respect to FIGS. 1, 2, and 3.

Cap wafer 104 of SAW device assembly 500 includes vias 502. In the exemplary embodiment, conductive interconnects 120 include printed conductive traces 302. Printed conductive traces 302 extend through associated vias 502 to provide a conductive path between components positioned on device wafer 102 and components positioned on cap wafer 104. In some embodiments, vias 502 may be formed through cap wafer 104 during the manufacture of cap wafer 104. Utilizing vias 502 may simplify the manufacturing process of SAW device assembly 500, for example, by eliminating the need for removal of a portion of cap wafer 104 to expose device pads 110.

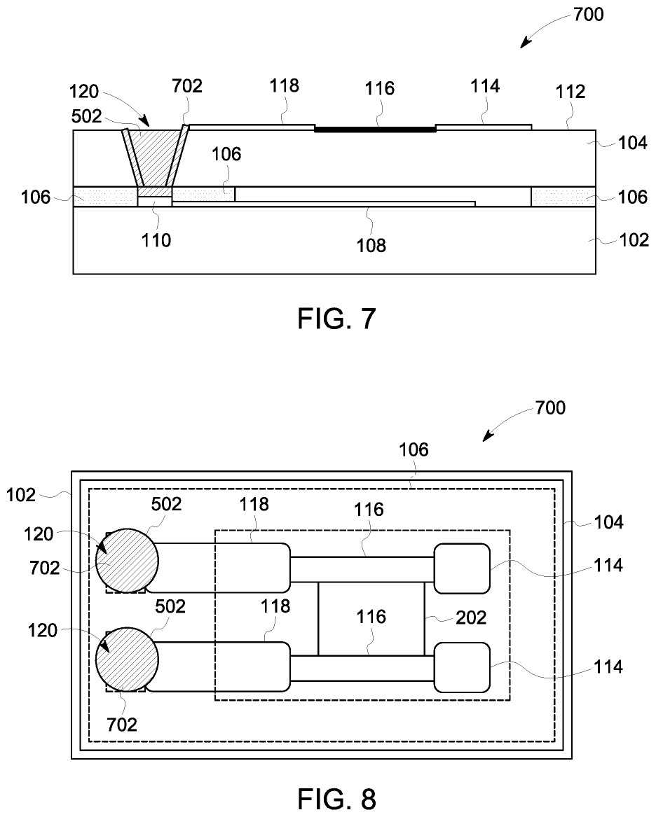

FIG. 7 depicts a side cross-sectional view of another SAW device assembly 700 according to an exemplary embodiment of the present disclosure. FIG. 8 is a top view of SAW device assembly 700. SAW device assembly 700 includes device wafer 102, cap wafer 104, seal layer 106, electrodes 108, device pads 110, contact pads 114, pad to pad interconnects 116, interconnect pads 118, conductive interconnects 120 (all shown in FIG. 1), passive electronic components 202 (shown in FIG. 2), and via 502 (shown in FIG. 5), which operate generally as described with respect to FIGS. 1, 2, and 5.

In the exemplary embodiment, conductive interconnects 120 include deposited conductive traces 702. Deposited conductive traces 702 may be formed through a direct metallization or sputtering process using, for example, titanium or copper. Deposited conductive traces 702 are electrically coupled to associated device pads 110 and interconnect pads 118 and provide a conductive path between components positioned on device wafer 102 and components positioned on cap wafer 104. Deposited conductive traces 702 extend through associated vias 502 in cap wafer 104. Conductive traces 702 can be formed at the same time as contact pads 114, pad to pad interconnects 116, and interconnect pads 118.

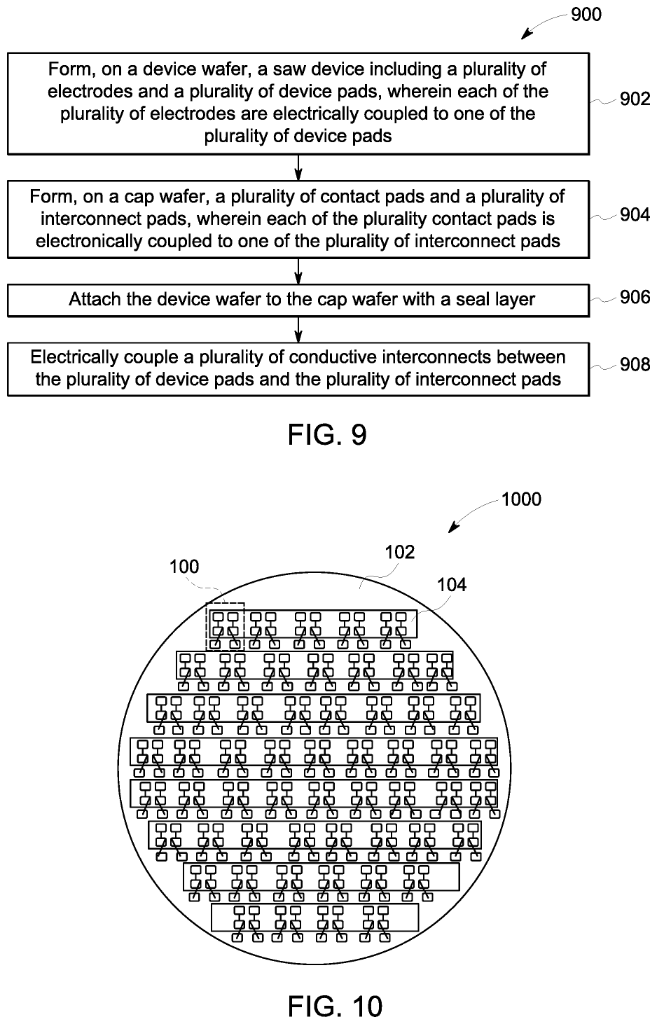

FIG. 9 depicts a method 900 of manufacturing a SAW device assembly such as SAW device assembly 100 shown in FIG. 1, SAW device assembly 300 shown in FIG. 3, SAW device assembly 500 shown in FIG. 5, or SAW device assembly 700 shown in FIG. 7.

Method 900 includes forming 902, on a device wafer, a SAW device including a plurality of electrodes and a plurality of device pads, wherein each of the plurality of electrodes are electrically coupled to one of the plurality of device pads. Method 900 further includes forming 904, on a cap wafer, a plurality of contact pads and a plurality of interconnect pads, wherein each of the plurality contact pads is electrically coupled to one of the plurality of interconnect pads. Method 900 further includes attaching 906 the device wafer to the cap wafer with a seal layer. Method 900 further includes electrically coupling 908 a plurality of conductive interconnects between the plurality of device pads and the plurality of interconnect pads.

FIG. 10 depicts a top view of a SAW wafer level assembly 1000. SAW wafer level assembly 1000 includes device wafer 102 and cap wafer 104. Device wafer 102 and cap wafer 104 are diced to form individual SAW device assemblies 100. In some embodiments, components such as, for example, contact pads 114, pad to pad interconnects 116, and interconnect pads 118 are formed on cap wafer 104 prior to dicing device wafer 102 and cap wafer 104. Thus, many device assemblies 100 can be efficiently manufactured simultaneously. Once device assembly 100 is cut from SAW wafer level assembly 1000, device assembly 100 can be integrated into a system by electrically coupling device assembly 100 to the system at contact pads 114. This can be done using solder attach, wirebond, ribbon bond, conductive epoxy, or any other conventional interconnect method.

The embodiments described herein include a SAW wafer level assembly including a device wafer having a plurality of electrodes and a plurality of device pads disposed thereon, the device wafer and the plurality of electrodes forming a SAW device, wherein each of the plurality of electrodes are electrically coupled to one of the device pads, a cap wafer attached to the device wafer with a seal layer, the cap wafer having a plurality of contact pads and a plurality of interconnect pads disposed thereon, the plurality of contact pads and the plurality of interconnect pads integral to the cap wafer, wherein each of the plurality of contact pads is electrically coupled to one of the interconnect pads, and a plurality of conductive interconnects, wherein each of the plurality of conductive interconnects are electrically coupled between one of the plurality of device pads and one of the plurality of interconnect pads.

An exemplary technical effect of the methods, systems, and apparatus described herein includes at least one of: (a) enabling connection of a SAW device to an external device by providing integral bond pads on a cap wafer of the SAW device; (b) improving reliability of the SAW device by including a cap wafer coupled to a device wafer of the SAW device with a seal layer (c) improving reliability of the SAW device by providing integral bond pads and interconnects; (d) reducing complexity of manufacture of the SAW device by utilizing integral bond pads and interconnects; and (e) reducing complexity of manufacture of the SAW device by providing passive electronic components disposed on the cap wafer.

Exemplary embodiments of a SAW wafer level assembly are described herein. The systems and methods of operating and manufacturing such systems and devices are not limited to the specific embodiments described herein, but rather, components of systems and/or steps of the methods may be utilized independently and separately from other components and/or steps described herein. For example, the methods may also be used in combination with other electronic systems, and are not limited to practice with only the electronic systems, and methods as described herein. Rather, the exemplary embodiment can be implemented and utilized in connection with many other electronic systems.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A device assembly comprising:
a device wafer;
a plurality of electrodes disposed on said device wafer, wherein said device wafer and said plurality of electrodes form a surface acoustic wave (SAW) device;
a plurality of device pads disposed on said device wafer, wherein each of said plurality of electrodes are electrically coupled to at least one of said device pads;
a cap wafer coupled to said device wafer through a seal layer, said cap wafer having a plurality of contact pads and a plurality of interconnect pads integral with a surface of said cap wafer, wherein each of said plurality of contact pads is electrically coupled to one of said plurality of interconnect pads; and
a plurality of conductive interconnects, wherein each of said plurality of conductive interconnects is electrically coupled between one of said plurality of device pads and one of said plurality of interconnect pads.

2. The device assembly of claim 1, wherein each of said plurality of conductive interconnects comprises a wirebond.

3. The device assembly of claim 1, further comprising a coating covering at least a portion of said device assembly.

4. The device assembly of claim 1, wherein each of said plurality of conductive interconnects comprises a printed conductive trace.

5. The device assembly of claim 1, wherein each of said plurality of conductive interconnects comprises a deposited conductive trace.

6. The device assembly of claim 1, wherein said cap wafer defines a plurality of vias, and wherein said plurality of conductive interconnects each extend through one of the plurality of vias.

7. The device assembly of claim 1, further comprising at least one passive electronic component disposed on said cap wafer.

8. The device assembly of claim 7, wherein said at least one passive electronic component comprises a surface mount component.

9. The device assembly of claim 7, wherein said at least one passive electronic component comprises a printed component.

10. The device assembly of claim 1, wherein said contact pads are configured for at least one of solder coupling and wirebond coupling.

11. A cap wafer assembly comprising:
a cap wafer comprising a plurality of contact pads and a plurality of interconnect pads integral with a surface of said cap wafer, wherein each of said plurality of contact pads is electrically coupled to one of said plurality of interconnect pads, and wherein said cap wafer is coupled to a surface acoustic wave (SAW) device including a device wafer, a plurality of electrodes disposed on the device wafer, and a plurality of device pads disposed on the device wafer and electrically coupled to at least one of the electrodes; and
a plurality of conductive interconnects, wherein each of said plurality of conductive interconnects is electrically coupled between one of the plurality of device pads and one of said plurality of interconnect pads.

12. The cap wafer assembly of claim 11, wherein each of said plurality of conductive interconnects comprises a wirebond.

13. The cap wafer assembly of claim 11, further comprising a coating covering at least a portion of said cap wafer assembly.

14. The cap wafer assembly of claim 11, wherein each of said plurality of conductive interconnects comprises a printed conductive trace.

15. The cap wafer assembly of claim 11, wherein each of said plurality of conductive interconnects comprises a deposited conductive trace.

16. The cap wafer assembly of claim 11, wherein said cap wafer defines a plurality of vias, and wherein said plurality of conductive interconnects each extend through one of the plurality of vias.

17. The cap wafer assembly of claim 11, further comprising at least one passive electronic component disposed on said cap wafer.

18. The cap wafer assembly of claim 17, wherein said at least one passive electronic component comprises a surface mount component.

19. The cap wafer assembly of claim 17, wherein said at least one passive electronic component comprises a printed component.

20. The cap wafer assembly of claim 11, wherein said contact pads are configured for at least one of solder coupling and wirebond coupling.
